(19) United States
(12) Patent Application Publication
(10) Pub. No.: US 2019/0363748 A1
(43) Pub. Date: Nov. 28, 2019

(54) Integrated Passive Device Transmission-Line Resonator

(71) Applicant: Qualcomm Incorporated, San Diego, CA (US)

(72) Inventors: Oleksandr Gavryliuk, San Diego, CA (US); Petro Komakha, Santee, CA (US); Wai San Wong, San Diego, CA (US); Jonghae Kim, San Diego, CA (US); Niranjan Sunil Mudakatte, San Diego, CA (US); Alexander Chernyakov, Munich (DE); Georgiy Sevskiy, Munich (DE)

(21) Appl. No.: 15/987,347

(22) Filed: May 23, 2018

(51) Int. Cl. H04B 1/40; H01P 1/20; H01P 3/08; H01P 7/08

(52) U.S. Cl. CPC H04B 1/40; H01P 1/20; H01P 3/08; H01L 24/04; H01L 2224/04042; H01L 2224/0401; H01P 7/08

(57) ABSTRACT

An integrated passive device transmission-line resonator is disclosed herein. An example structure of the transmission-line resonator includes a glass substrate having first and second sides, a ground plane, a dielectric layer, and features fabricated from two metal layers. A first metal layer, which is formed on the second side of the glass substrate, includes a first capacitor plate and a conductor that, in conjunction with a portion of the ground plane, realizes a transmission line. A portion of the dielectric layer is disposed between the first capacitor plate and a second capacitor plate, which is formed from a second metal layer and positioned axially above the first capacitor plate, to form a capacitor. A smooth interface between a surface of the second side of the glass substrate and the conductor reduces transmission losses of signals propagating across the transmission line and increases performance of the transmission-line resonator.

### TECHNICAL FIELD

This disclosure relates generally to communication with an electronic device and, more specifically, to a transmission-line resonator fabricated as part of an integrated passive device having a glass substrate.

### BACKGROUND

Electronic devices include traditional computing devices such as desktop computers, notebook computers, tablet computers, smart phones, wearable devices like a smartwatch, internet servers, and so forth. However, electronic devices also include other types of devices with computing power such as personal voice assistants, thermostats, automotive electronics, robotics, devices embedded in other machines like refrigerators and industrial tools, security devices, Internet-of-Things (IoT) devices, and the like. These various electronic devices provide information, entertainment, social interaction, security, safety, productivity, transportation, and other services to human users. Thus, electronic devices play crucial roles in many aspects of modern society.

Many of the services provided by electronic devices in today's interconnected world depend at least partly on electronic communications, including wireless communications. Such electronic devices are designed to communicate wireless signals in accordance with some wireless standard, such as one promulgated in accordance with 3rd Generation Partnership Project Long-Term Evolution (3GPP LTE). The Fifth Generation (5G) wireless standard is intended to enable devices to communicate signals using frequencies at or near the super high frequency (SHF) and extremely high frequency (EHF) spectrum and with wavelengths at or near centimeter and millimeter wavelengths. As part of communicating such signals, electrical filters may be used to isolate signals from a particular range of frequencies, or frequency band, within the SHF or EHF spectrum. Electrical filters are typically formed using capacitors coupled to inductors (e.g., an LC filter).

However, the electrical filters designed for devices that operate in accordance with the Fourth Generation (4G) wireless standard are proving inadequate to handle the higher frequencies intended for 5G-capable devices. Accordingly, engineers and device manufacturers are striving to develop electrical filters that can process SHF and EHF frequencies for the smart phones and other electronic devices that are to communicate with 5G technologies.

### SUMMARY

Aspects of articles of manufacture or physical constructs, systems, and methods relating to a transmission-line resonator having an integrated passive device glass substrate are disclosed. The transmission-line resonator can be used as part of a transmission-line filter that adjusts characteristics of high-frequency signals between, for instance, a mixer and an amplifier of a wireless transceiver. An example structure of the transmission-line resonator includes a glass substrate having first and second sides, a ground plane, a dielectric layer, and features fabricated from two metal layers. The ground plane is disposed on the first side of the glass substrate. A first metal layer, which is formed on the second side of the glass substrate, includes a first capacitor plate and a conductor that, in conjunction with a portion of the ground plane, realizes a transmission line. A portion of the dielectric layer is disposed between the first capacitor plate and a second capacitor plate, which is formed from a second metal layer and positioned axially above the first capacitor plate, to form a capacitor. A smooth interface between a surface of the second side of the glass substrate and the conductor reduces transmission losses of signals propagating across the transmission line and increases performance of the transmission-line resonator.

In an example aspect, an apparatus is disclosed. The apparatus includes a glass substrate having a first side and a second side that is opposite the first side. A ground plane is disposed on the first side of the glass substrate. A transmission line of the apparatus includes a conductor, which is formed from a first metal layer disposed on the second side of the glass substrate, and a portion of the ground plane. A portion of a dielectric layer is disposed between a first capacitor plate formed from the first metal layer and a second capacitor plate formed from a second metal layer.

In an example aspect, a system is disclosed. The system includes a glass substrate, a ground plane disposed on a side of the glass substrate, and a first metal layer disposed on another side of the glass substrate. The system also includes a second metal layer disposed on the other side of the glass substrate beyond the first metal layer and a dielectric layer disposed between the first metal layer and the second metal layer. The system also includes a transmission-line resonator that includes propagation means for propagating a signal along at least a portion of the glass substrate. The transmission-line resonator further includes a first capacitor plate formed from the first metal layer, a second capacitor plate formed from the second metal layer, and a portion of the dielectric layer disposed between the first capacitor plate and the second capacitor plate.

In an example aspect, a method of filtering a signal is disclosed. The method includes accepting the signal at a node and propagating the signal along a conductor and a ground plane that are separated by a glass substrate. The method additionally includes routing the signal to a capacitor including a first plate and a second plate that are separated by a portion of a dielectric layer where the second plate is disposed on a same side of the glass substrate as the conductor. Responsive to the propagating and the routing, the method adjusts a characteristic of the signal. The method further includes forwarding the signal at another node.

In an example aspect, an apparatus is disclosed. The apparatus includes a glass substrate, a first metal layer, a ground plane, a second metal layer, and a dielectric layer. The first metal layer is disposed on the glass substrate and includes a conductor and a first set of capacitor plates. The ground plane is disposed on an opposite side of the glass substrate from the first metal layer. The conductor and a portion of the ground plane are configured to operate as a transmission line. The second metal layer includes a second set of capacitor plates, and a portion of the dielectric layer is disposed between the first set of capacitor plates and the second set of capacitor plates.

### BRIEF DESCRIPTION OF DRAWINGS

FIG. 1 illustrates an example environment for filtering a high-frequency signal, such as filtering within an electronic device between a modem and an antenna.

FIGS. 2-1 and 2-2 illustrate a configuration of an example transmission-line resonator and a configuration of an example transmission-line filter, respectively.

FIGS. 3-1 and 3-2 illustrate cross-section views of an example material stack used to form a transmission-line resonator.

FIG. 4 illustrates a perspective view of an example integrated passive device having a transmission-line resonator.

FIGS. 5-1 and 5-2 illustrate a top view and a corresponding, simplified schematic, respectively, of an example transmission-line resonator having an array of series-connected, cross-coupled capacitors.

FIG. 6 illustrates an example process performed by a transmission-line filter, including a transmission-line resonator, that is adjusting a characteristic of a signal.

FIGS. 7-1 and 7-2 illustrate an example process performed by various semiconductor manufacturing tools to fabricate a transmission-line resonator as part of an integrated passive device.

### DETAILED DESCRIPTION

Conventional techniques for implementing an electrical filter as part of an integrated passive device typically rely on a construct that uses four or more metal layers and includes at least a capacitor and an inductor. A portion of such an electrical filter (e.g., the inductor of the electrical filter) resides on a layer of a dielectric material as part of the construct. In addition to manufacturing expenses associated with using the four or more metal layers, a surface roughness of an interface between the inductor and the layer of the dielectric material leads to insertion losses that compromise performance of the electrical filter.

In contrast, techniques for implementing a transmission-line filter using a transmission-line resonator that is constructed using two metal layers are described herein. A portion of the transmission-line resonator (e.g., a conductor of a transmission line) resides on a surface of a glass substrate of the integrated passive device. The reduction in metal layer count reduces manufacturing costs of the filter, while the smooth interface between the conductor and the surface of the glass substrate reduces insertion losses and improves performance of the transmission-line filter.

In some implementations, a first metal layer, disposed on a first side of a glass substrate, includes a feature of a conductor that has a region including a first capacitor plate. A second metal layer, disposed on a dielectric residing over the first metal layer, forms a feature of a second capacitor plate. A ground plane resides on a second side of the glass substrate, opposite the first side of the glass substrate. The conductor and a portion of the ground plane jointly form a transmission line.

In some implementations, a transmission-line resonator may perform at least part of a filtering process performed by a transmission-line filter. In operation, the transmission-line resonator adjusts one or more characteristics of a signal as the signal propagates over the transmission-line resonator and through a transmission-line filter. In particular, filtering signals associated with Fifth Generation (5G) communication standards benefits from the described transmission-line resonator, in part due to a reduction in insertion losses associated with the smooth interface between the conductor of the transmission line and the glass substrate. This includes filtering signals within the super high frequency (SHF) portion (e.g., 3 to 30 GHz) of the electromagnetic (EM) spectrum and signals within the extremely high frequency (EHF) portion (e.g., 30 GHz to 300 GHz) of the EM spectrum.

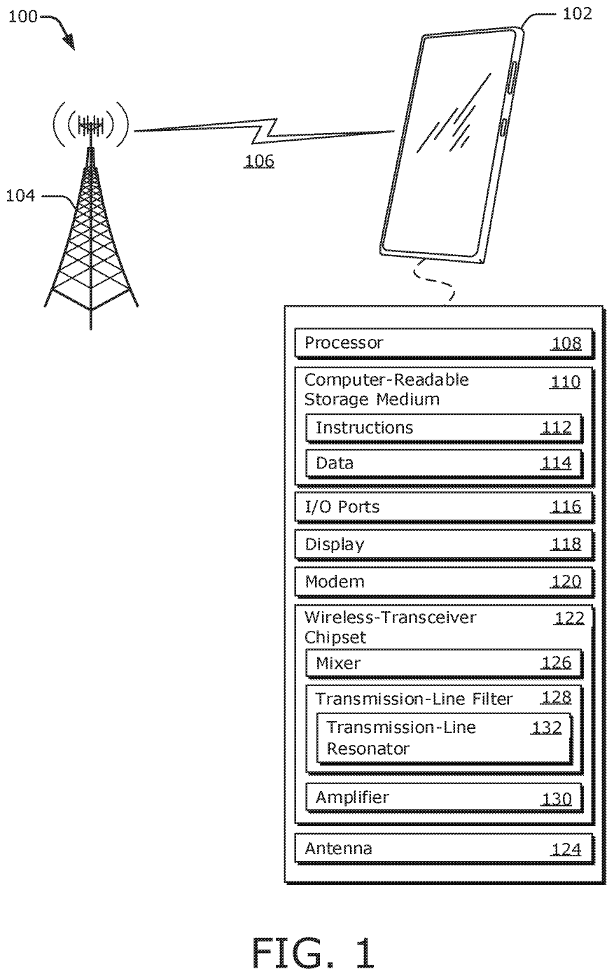

FIG. 1 illustrates an example environment 100 for filtering a high-frequency signal, such as filtering within an electronic device between a modem and an antenna. In the example environment 100, a computing device 102 communicates with a base station 104 through a wireless communication link (wireless link 106). In this example, the computing device is implemented as a smart phone. However, the computing device 102 may be implemented as any suitable computing or electronic device, such as a modem, a cellular base station, a broadband router, an access point, a cellular phone, a gaming device, a navigation device, a media device, a laptop computer, a desktop computer, a tablet computer, a server, a network-attached storage (NAS) device, an Internet-of-Things (IoT) device, a smart appliance, a vehicle-based communication device, a radio apparatus, and so forth.

The base station 104 communicates with the computing device 102 via the wireless link 106, which may be implemented as any suitable type of wireless link. Although depicted as a tower of a cellular network, the base station 104 may represent or be implemented as another device, such as a satellite, cable television head-end, terrestrial television broadcast tower, access point, peer-to-peer device, mesh network node, fiber optic line, and so forth. Therefore, the computing device 102 may communicate with the base station 104 or another device via a wired connection, a wireless connection, or a combination thereof.

The wireless link 106 can include a downlink of data or control information communicated from the base station 104 to the computing device 102 and an uplink of other data or control information communicated from the computing device 102 to the base station 104. The wireless link 106 may be implemented using any suitable communication protocol or standard, such as 3rd Generation Partnership Project Long-Term Evolution (3GPP LTE), Fifth Generation (5G), IEEE 802.11, IEEE 802.16, Bluetooth™, and so forth.

The computing device 102 includes a processor 108 and a computer-readable storage medium 110 (CRM 110). The processor 108 may include any type of processor, such as an application processor or multi-core processor, that executes processor-executable code stored by the CRM 110. The CRM 110 may include any suitable type of data storage media, such as volatile memory (e.g., random access memory (RAM)), non-volatile memory (e.g., Flash memory), optical media, magnetic media (e.g., disk or tape), and so forth. In the context of this disclosure, the CRM 110 is implemented to store instructions 112, data 114, and other information of the computing device 102, and thus does not include transitory propagating signals or carrier waves.

The computing device 102 may also include input/output ports 116 (I/O ports 116) and a display 118. The I/O ports 116 enable data exchanges or interaction with other devices, networks, or users. The I/O ports 116 may include serial ports (e.g., universal serial bus (USB) ports), parallel ports, audio ports, infrared (IR) ports, and so forth. The display 118 presents graphics of the computing device 102, such as a user interface associated with an operating system, program, or application. Alternately or additionally, the display 118 may be implemented as a display port or virtual interface, through which graphical content of the computing device 102 is presented.

The computing device 102 also includes a modem 120, a wireless-transceiver chipset 122, and an antenna 124 for communicating wirelessly. In an example of wireless communication, the antenna 124 of the computing device 102 radiates energy to transmit data via the wireless link 106 to the base station 104. In such an example, the modem 120 may modulate signals corresponding to the data originating from the computing device 102. The wireless-transceiver chipset 122 of the computing device 102 may then condition the signals corresponding to the data as they propagate from the modem 120 to the antenna 124. The wireless-transceiver chipset 122 includes a mixer 126, a transmission-line filter 128, and an amplifier 130.

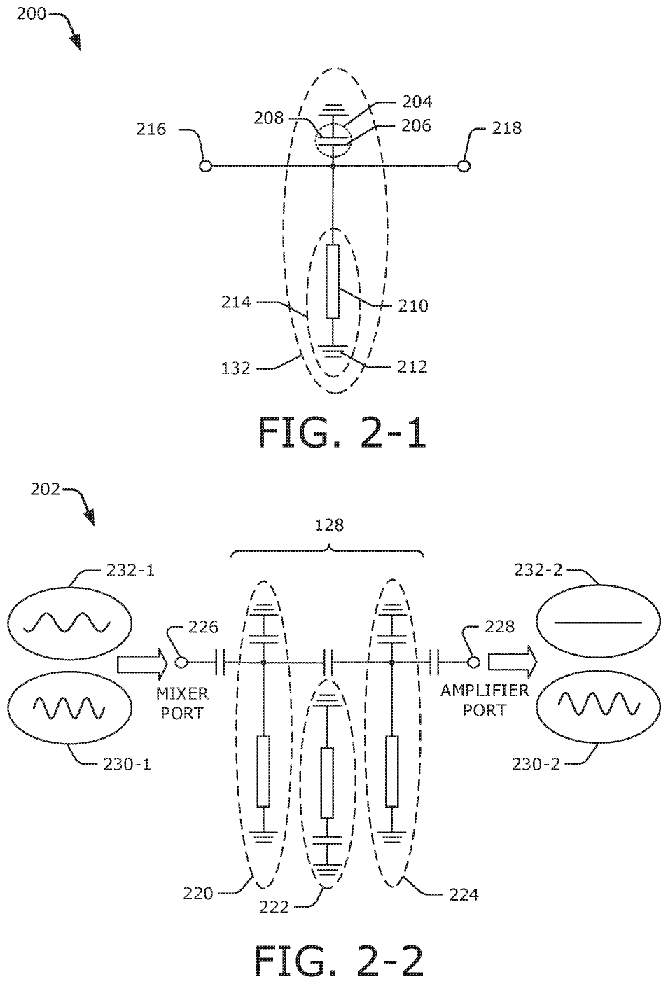

The mixer 126 can perform upconversion or downconversion to increase or decrease, respectively, a frequency of a signal. The transmission-line filter 128 can filter one or more frequencies out of a signal, such as with a bandpass, a lowpass, or a band reject filter. For instance, the transmission-line filter 128 can filter electrical signals to allow those of a determined frequency range to pass from the modem to the antenna or vice versa. The amplifier 130 can amplify a power level of transmitted or received signals. For example, the amplifier 130 can boost the amplitude of transmission signals prior to radiating energy from the antenna 124 or prior to forwarding received signals to the transmission-line filter 128 or the mixer 126. Further, as shown, the transmission-line filter 128 can include one or more transmission-line resonators 132. Each transmission-line resonator 132 may contribute to the filtering of signals as performed by the transmission-line filter 128, as described with reference to FIGS. 2-1 and 2-2.

FIGS. 2-1 and 2-2 respectively illustrate a configuration 200 of an example transmission-line resonator and a configuration 202 of an example transmission-line filter, such as the transmission-line resonator 132 and the transmission-line filter 128 of FIG. 1. As shown in FIG. 2-1, the transmission-line resonator 132 includes a capacitor 204 including a first capacitor plate 206 and a second capacitor plate 208. Also included as part of the transmission-line resonator 132 is a conductor 210. The conductor 210, in conjunction with a portion of a ground plane 212, forms a transmission line 214. The transmission-line resonator 132 may be fabricated as an integrated passive device as described herein. For both transmission and reception operations, a transmission-line filter 128, and a transmission-line resonator 132 thereof, can be designed to accommodate propagating signals having some target operational frequency. To do so, at least one dimension (e.g., a length) of a given conductor 210 can be selected such that a reactance based on the conductor 210 and a capacitance of at least one associated capacitor (e.g., of a same transmission-line resonator) has a corresponding resonance frequency that is related to the operational frequency. For example, a resonance frequency of a joint reactance from the transmission line and the capacitor of a transmission-line resonator can be set approximately equal to the target operational frequency such that a targeted frequency range is passed by the transmission-line filter but other frequencies are substantially attenuated.

In a transmission operation, for example, the transmission-line resonator 132 provides an electrical or electromagnetic path for a signal propagating between a first node 216 and a second node 218. The transmission-line resonator 132 accepts the signal at the first node 216, propagates the signal along the conductor 210 and the ground plane 212 of the transmission line 214, and routes the signal to the capacitor 204. Responsive to the propagating and routing, the transmission-line resonator 132 adjusts a characteristic of the signal and forwards the signal at the second node 218. In some instances, the transmission-line resonator 132 may also behave bi-directionally. Thus, the transmission-line resonator 132 can also accept the signal at the second node 218 and forward the signal at the first node 216.

As illustrated by FIG. 2-2 and in the configuration 202, the transmission-line filter 128 may include a plurality of transmission-line resonators 220, 222, and 224. As part of the configuration 202, each of the transmission-line resonators 220-224 may have a construct similar to that of the example transmission-line resonator 132. Additionally, and as illustrated by the transmission-line resonator 222, a transmission-line resonator may “float” electrically with respect to an input node or an output node of the transmission-line filter 128.

To facilitate operation as part of the wireless-transceiver chipset 122, the transmission-line filter 128 also includes a first node, e.g. a mixer port 226, and a second node, e.g. an amplifier port 228. Each of the transmission-line resonators 220-224 are arranged approximately in parallel with respect to each other but substantially perpendicular relative to a direction of propagation for a signal traveling between the two ports. The transmission-line filter 128 electrically connects the mixer 126 to the amplifier 130 (both of FIG. 1) and provides an electrical or electromagnetic path for a signal propagating between the mixer 126 and the amplifier 130, in either direction.

Continuing with the illustration of FIG. 2-2, in one instance the propagating signal may include a signal such as signal 230-1, which is driven at a frequency range that resonates with a resonant frequency of the transmission-line filter 128. In this instance, and in response to the propagating and routing, the transmission-line filter 128 passes the signal and forwards the signal in the form of the signal 230-2 via the amplifier port 228.

In another instance, the propagating signal may include a signal such as signal 232-1, which is driven at a frequency range that does not match a resonant frequency of the transmission-line filter 128. In this other instance, and in response to the propagating and routing, the transmission-line filter 128 rejects the non-resonant frequency (e.g., adjusts a characteristic) of the propagating signal. The transmission-line filter 128 forwards the signal in the form of signal 232-2, which has a significantly attenuated amplitude in the rejected frequency range. In effect, filtering of the signal 232-1 can render a power of the signal 232-2 as being substantially negligible prior to forwarding the signal toward an amplifier (via the amplifier port 228) in an example transmission operation.

As illustrated by FIG. 2-2, the transmission-line filter 128 passes resonant frequencies but rejects other frequencies to thereby filter certain frequencies of a signal (e.g., to adjust a characteristic of the signal). For example, the transmission-line filter 128 can perform as a band-pass filter and may be applicable to filtering signals within the super high frequency (SHF) portion (e.g., 3 to 30 GHz) of the electromagnetic (EM) spectrum or signals within the extremely high frequency (EHF) portion (e.g., 30 GHz to 300 GHz) of the EM spectrum. Although the example depicted in FIG. 2-2 pertains primarily to a signal transmission operation performed as part of a transmit path between a mixer and an amplifier, a transmission-line filter 128 can be disposed elsewhere along a transmit path. For example, a transmission-line filter 128 can be positioned between a transmit power amplifier (PA), including a main or final PA, and an antenna, such as the antenna 124 of FIG. 1. Further, although the example depicted in FIG. 2-2 pertains primarily to a transmission operation performed as part of a transmit path, a transmission-line filter 128 can also be deployed as part of a receive path. Thus, a signal incoming at one port of a transmission-line filter 128 can be accepted from an antenna or a low-noise amplifier (LNA), and the signal outgoing from another port of the transmission-line filter 128 can be provided to an LNA or a mixer, respectively. Generally, as described otherwise herein, a transmit path or a receive path of wireless transceiver can have other components, such as other filters and switches and amplifiers, and a transmission-line filter 128 can be disposed anywhere along either a transmit or a receive signaling path.

FIGS. 3-1 and 3-2 illustrate cross-section views (a side view 300 and an end view 302) of an example material stack used to form a transmission-line resonator, such as the transmission-line resonator 132 of FIGS. 1 and 2 (including the transmission-line resonators 220-224). Semiconductor manufacturing techniques that include metal deposition (e.g., chemical vapor deposition (CVD), sputtering, physical vapor deposition (PVD), or plating), photolithography (e.g., masking, exposing, and developing either a positive or a negative photoresist), etching (e.g., dry etching, wet etching, or laser drilling), and so forth may be applied to manufacture the material stack.

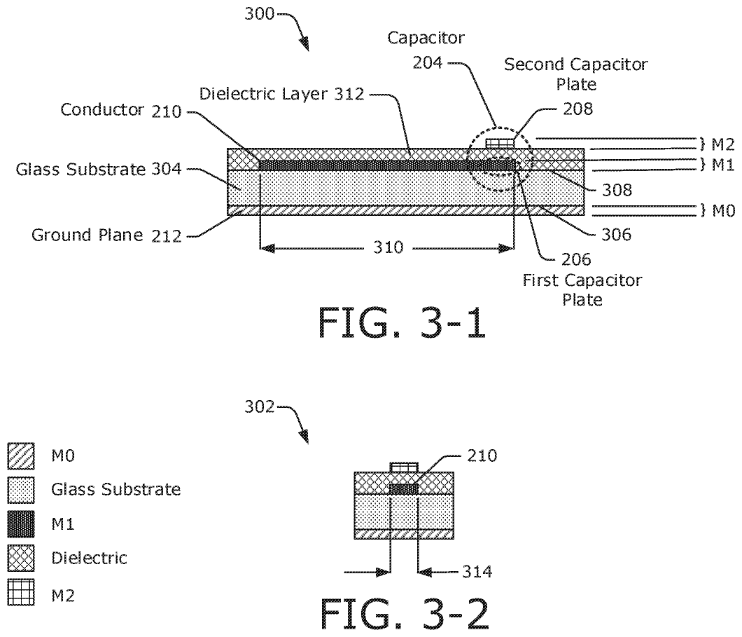

As illustrated by FIG. 3-1 and the side view 300, the example material stack includes a glass substrate 304 that has a first side 306 and a second side 308 that is opposite the first side 306. The conductor 210 is formed from a first metal layer (e.g., M1) on the second side 308 of the glass substrate 304. The conductor 210 is formed to have a conductor length 310. In some implementations, the conductor 210 is also formed to have a region comprising the first capacitor plate 206. Although the first capacitor plate 206 and the conductor 210 are illustrated as a continuous, uninterrupted portion of the first metal layer M1 (e.g., as being contiguous with one another), in some implementations the first capacitor plate 206 and the conductor 210 may be discontinuous or separate from one another within the first metal layer M1 (e.g., separated by part of a dielectric material). Although not visible in FIG. 3-1, the first metal layer M1 may include multiple conductors and multiple first capacitor plates corresponding to multiple other transmission-line resonators (e.g., positioned “behind” the conductor 210 and the first capacitor plate 206 of the depicted transmission-line resonator) that are each part of a same or a different transmission-line filter 128 (of FIGS. 1 and 2).

Forming the conductor 210 and the first capacitor plate 206 from the first metal layer M1 (in situ) affords manufacturing process control and tolerances that yield a common thickness for the conductor 210 and the first capacitor plate 206. In certain instances, manufacturing processes may produce the conductor 210 to have a conductor length 310 that is less than ½ of a wavelength of a particular operating frequency of a signal being filtered by an associated transmission-line filter 128. For example, for an operating frequency that is at or near a super high frequency (SHF) of 30 GHz, the conductor length 310 can be <0.5 millimeter (mm). Similarly, for an operating frequency that is at or near an extremely high frequency (EHF) of 300 GHz, the conductor length 310 can be <0.05 millimeter (mm).

Surface roughness conditions of the second side 308 can impact electrical signaling performance of the transmission-line resonator 132. Surface roughness conditions of the second side 308 of the glass substrate 304 can, in certain instances, be <1 nanometer (nm) and provide a smooth interface between the second side 308 and the conductor 210. Such a smooth interface can impact electrical performance of the transmission-line resonator 132 by reducing insertion losses that are experienced by a signal propagating over or through the conductor 210 as compared to if a conductor were formed on a surface with a surface roughness >1 nm (e.g., approximately 300 nm for some metal surfaces). In certain instances, a silicon-based substrate that undergoes electrochemical polishing to achieve desired surface roughness conditions may be substituted for the glass substrate 304. Thus, in these manners, the conductor 210 can provide a propagation mechanism for propagating a signal along at least a portion of the glass substrate 304.

Continuing with FIG. 3-1, a second capacitor plate 208 is formed from a second metal layer (e.g., M2) and is positioned substantially in a vertical alignment with the first capacitor plate 206. For example, if an axis passes through a center of the first capacitor plate 206, with the axis being substantially perpendicular to the second side 308 of the glass substrate 304, such an axis also passes through the second capacitor plate 208. In other examples, the second capacitor plate 208 at least partially overlaps the first capacitor plate 206.

FIG. 3-1 also illustrates the ground plane 212 disposed on the first side 306 of the glass substrate 304. The ground plane can be formed from another metal layer (e.g., M0). The conductor 210, in conjunction with a portion of the ground plane 212, can realize a transmission line (e.g., the transmission line 214 of FIG. 2-1) of a transmission-line resonator. The portion of the ground plane 212 can include, for example, an area substantially comparable to that of the conductor 210 in a region of the ground plane 212 that is vertically or axially aligned with the conductor 210.

The first metal layer M1, the second metal layer M2, and the other metal layer M0 are typically, as part of a material stack layering, deposited individually. Furthermore, the material stack can be layered such that the first metal layer M1, the second metal layer M2, and the other metal layer M0 are each of a like material, are each of a different material, or are a combination thereof. Example metal materials for the metal layers include copper (Cu), aluminum (Al), titanium (Ti), tungsten (W), combinations thereof, and so forth.

A portion of a dielectric layer of material 312 is disposed between the first capacitor plate 206 and the second capacitor plate 208 such that a capacitor 204 of the transmission-line resonator 132 can be realized. The dielectric layer of material 312 may be selected with a desired dielectric or permittivity constant. Example materials for the dielectric layer of material 312 include polyimide (PI), silicon nitride (SiNiₓ), silicon oxynitride (SiOₓN_{y}), borophosphosilicate glass (BPSG), and aluminum oxide (AlOₓ), combinations thereof, and so forth.

As illustrated by FIG. 3-2 and end view 302, the conductor 210 has a conductor width 314. In one example implementation of the transmission-line resonator 132, the conductor width 314 may have a ratio with respect to the conductor length 310 that is approximately 1/10th of the conductor length 310. Accordingly, in an example instance where the conductor length 310 is one-half of a millimeter (0.5 mm), the conductor width 314 can be one-twentieth of a millimeter (0.05 mm). However, the illustrated components can be produced with different sizes.

The construct of the transmission-line resonator 132, using the first metal layer (M1) and the second metal layer (M2) as depicted in FIGS. 3-1 and 3-2, results in an improved quality factor (e.g., a Q factor) of the transmission-line resonator 132 when compared to another resonator having a conductor formed from an upper third metal layer (M3) disposed on a dielectric material or an upper fourth metal layer (M4) disposed on a dielectric material. The improved quality factor of the transmission-line resonator 132 reduces dampening of a signal as it propagates over or through the transmission-line resonator 132 and, in effect, lessens energy losses. The construct also results in an increase in a linear response of the signal as it propagates over or through the transmission-line resonator 132 (e.g., along a portion of the glass substrate 304). The transmission-line resonator 132, when used as part of the transmission-line filter 128, can thus enable the transmission-line filter 128 to better handle the higher frequencies planned for 5G communications.

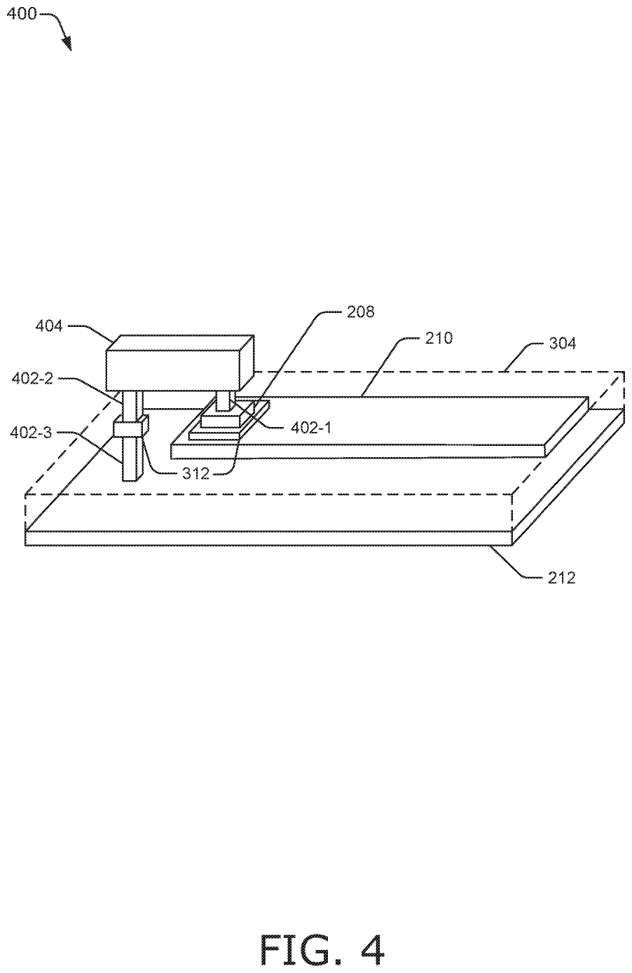

FIG. 4 illustrates a perspective view of an example integrated passive device having a transmission-line resonator. The transmission-line resonator is an example implementation of the transmission-line resonator 132 as illustrated in FIGS. 1 and 2 and includes portions of the material stacks illustrated in FIG. 3-1 and FIG. 3-2. The integrated passive device includes the conductor 210, the ground plane 212, and the glass substrate 304. Also included in the illustration of the integrated passive device is the second capacitor plate 208 and the dielectric layer of material 312 (portions of the dielectric layer of material 312 are illustrated for clarity).

The integrated passive device includes a connector 404 fabricated from an optional third metal layer (M3) (not explicitly indicated) and vertical interconnect access (via) connections 402-1 through 402-3 that, in combination, electrically connect the second capacitor plate 208 to the ground plane 212. The connector 404 of the third metal layer is optional, pending layout and electrical routing considerations when constructing the integrated passive device. Semiconductor manufacturing processes, such as metal deposition, photolithography, and etching may be used to fabricate the connector 404 and the vertical interconnect access (via) connections 402-1 through 402-3, such as if the via connections 402-1 through 402-3 are routed vertically through the dielectric layer of material 312 and the glass substrate 304.

FIGS. 5-1 and 5-2 illustrate a top view 500 and a corresponding, simplified schematic 502 of an example transmission-line resonator having an array of series-connected, cross-coupled capacitors. The transmission-line resonator is another example implementation of the transmission-line resonator 132 of FIG. 1.

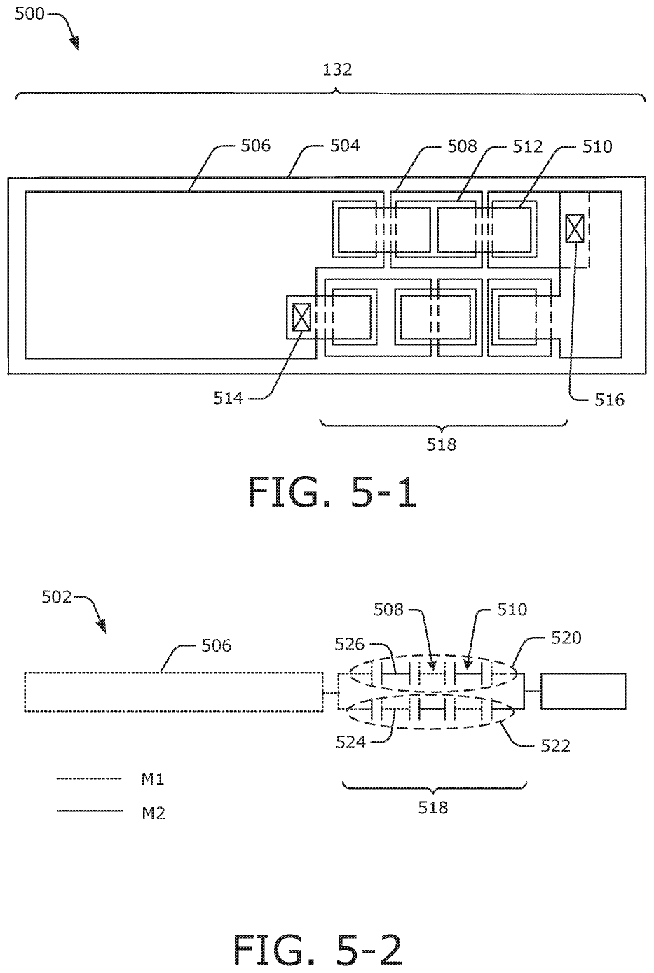

As illustrated by the top view 500 of FIG. 5-1, the transmission-line resonator 132 includes a glass substrate 504. A first metal layer is disposed on the glass substrate, forming a conductor 506 and a first set of capacitor plates, the first set of capacitor plates including one or more capacitor plates such as capacitor plate 508. Continuing with the illustration of the top view 500, the transmission-line resonator 132 comprises a second metal layer including a second set of capacitor plates, the second set of capacitor plates including one or more capacitor plates such as capacitor plate 510. Portions of a dielectric layer of material 512 are disposed between the first set of capacitor plates and the second set of capacitor plates (the top view 500 illustrates those portions of the dielectric layer of material 512 for simplicity). Additionally, vertical interconnect access (via) connections 514 and 516 are depicted with rectangles having an internal “X”. As depicted, via connection 514 and via connection 516 connect features formed from the first metal layer (M1) to features formed from the second metal layer (M2).

As illustrated by the simplified schematic 502 of FIG. 5-2, the transmission-line resonator 132 includes the first set of capacitor plates formed from the first metal layer and the second set of capacitor plates formed from the second metal layer. The first set of capacitor plates include, for example, the capacitor plate 508 while the second set of capacitor plates includes the capacitor plate 510. Further, and as illustrated by the simplified schematic 502 of FIG. 5-2, the first set of capacitor plates and the second set of capacitor plates may form an array of series-connected, cross-coupled capacitors 518.

As illustrated, the array of series-connected, cross-coupled capacitors 518 is comprised of a first group of capacitors 520 coupled in parallel with a second group of capacitors 522. Furthermore, the first group of capacitors 520 and the second group of capacitors 522 each include, e.g., four capacitors that are consecutively connected in a series. For example, the first group of capacitors 520 is connected together in a first series of capacitors and the second group of capacitors 522 is connected together in a second series of capacitors. The combination of parallel coupling and the series connections, as applied to the first group of capacitors 520 and the second group of capacitors 522, forms a 2×4 array. Other arrays of capacitors are possible as part of the transmission-line resonator 132, such as a 2×8 array, a 3×6 array, and so forth.

Furthermore, as illustrated and as part of the cross-coupling of the array of series-connected, cross coupled capacitors 518, adjacent connections between consecutive capacitors in the first group of capacitors 520 and the second group of capacitors 522 are disposed in different metal layers. As illustrated, connection 524 and connection 526 are adjacent to each other in terms of a physical arrangement of the array, but each connection is formed in a different metal layer (e.g., the connection 524 connects two capacitor plates formed as part of the first metal layer (M1) while the connection 526 connects two capacitor plates formed as part of the second metal layer (M2)).

The arrangement of the capacitor plates in the form of the array of series-connected, cross-coupled capacitors 518 reduces parasitic components that might be associated with communicating at EHF and SHF frequencies of the electromagnetic frequency spectrum. Additional benefits of the transmission-line resonator 132 having the array of series-connected, cross-coupled capacitors 518 include, for example, the ability to increase a thickness of the dielectric layer of material 512 during manufacturing and higher performance in terms of breakdown voltage, electro-static discharge (ESD), and linearity, which are effective to attain a desired performance of the transmission-line resonator 132. Thus, the array of series-connected, cross-coupled capacitors 518 can provide a linearity mechanism for increasing a linear response of a signal propagated along a portion of the glass substrate 504. Also, as part of previously-described transmission-line filter 128 examples, a transmission-line resonator 132 having the array of series-connected, cross-coupled capacitors 518 is configurable to accept and adjust a range of frequencies of a signal, which is operating in a frequency spectrum ranging from 3 GHz to 300 GHz, that are to be passed or rejected by the transmission-line filter 128.

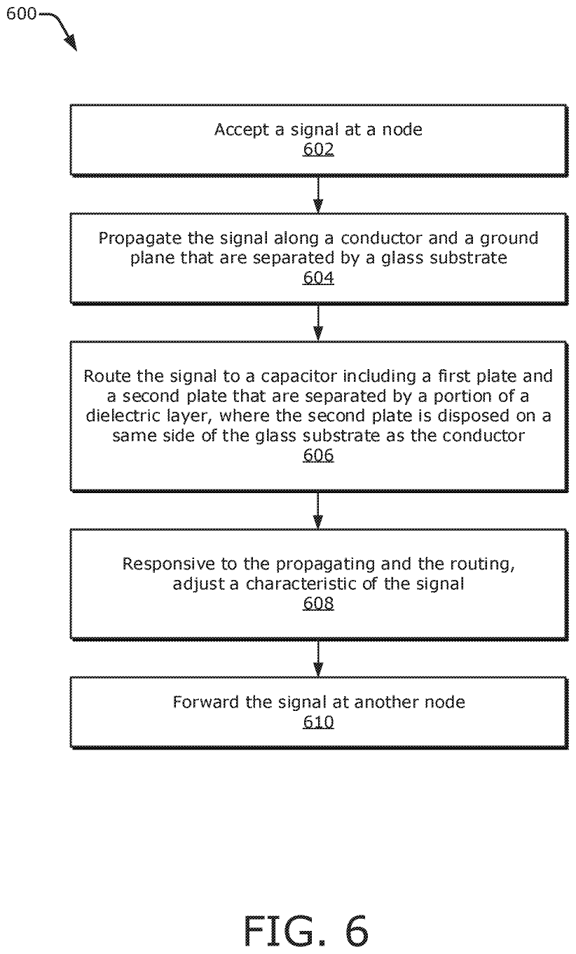

FIG. 6 illustrates an example process 600 performed by a transmission-line filter, including a transmission-line resonator, that is adjusting a characteristic of a signal. Adjusting the characteristic of the signal may entail rejecting some frequencies of the electromagnetic spectrum that are contained in the signal or passing a subset of frequencies of the electromagnetic spectrum. The process 600 is described in the form of a set of blocks 602-610 that specify operations that can be performed. However, operations are not necessarily limited to the order shown in FIG. 6 or described herein, for the operations may be implemented in alternative orders or in fully or partially overlapping manners. Thus, operations represented by the process 600 may be performed by the transmission-line filter 128, including the transmission-line resonator 132, of the computing device 102 of FIG. 1.

At 602, the transmission-line filter 128 accepts a signal with a first characteristic at a node. As an example, the signal may be accepted at a first node (e.g. the mixer port 226) from the mixer 126 of the wireless-transceiver chipset 122. And, continuing with this example, the first characteristic may include a wavelength corresponding to a frequency within a frequency spectrum ranging from 3 GHz to 300 GHz.

At 604, the transmission-line resonator 132 propagates the signal along the conductor 210 and the ground plane 212 that are separated by the glass substrate 304. In certain instances, the conductor 210 can be fabricated such that a size parameter thereof is dimensioned relative to a wavelength of a signal at which the transmission-line filter 128 is configured to operate. For example, a length of the conductor 210 can be configured to be one-half of a wavelength of a predetermined frequency or frequency range. For example, if the predetermined frequency is 300 GHz, a wavelength of the predetermined frequency would be 1 millimeter (mm), and the conductor 210 can be fabricated to have a length of 0.5 mm.

At 606 the transmission-line resonator 132 routes the signal to the capacitor 204. The capacitor 204 includes the first capacitor plate 206, which may be formed as part of the conductor 210, and the second capacitor plate 208. The second capacitor plate 208 is disposed on a same side of the glass substrate 304 as the conductor 210 and is separated from the first capacitor plate 206 by a portion of the dielectric layer of material 312 to form the capacitor 204. In some instances, the capacitor 204 may be part of the array of series-connected, cross-coupled capacitors 518 as illustrated by FIGS. 5-1 and 5-2.

At 608, the transmission-line filter 128 adjusts a characteristic of the signal in response to propagating the signal at 604 and the routing the signal at 606. In accordance with the adjustment, the transmission-line filter 128 produces a filtered signal having a second characteristic, where the second characteristic is a resultant effect of a combination of transmission-line resonators. The second characteristic may, for example, be such that frequencies that resonate with the transmission-line filter 128 are passed by the transmission-line filter 128 while frequencies that do not resonate with the transmission-line filter 128 are blocked. Furthermore, the second characteristic may include a wavelength corresponding to a frequency within an electromagnetic frequency spectrum ranging from 3 GHz to 300 GHz. Such a wavelength may or may not match the wavelength of the first frequency characteristic of the signal as accepted at 602.

At 610, the transmission-line filter 128 forwards the filtered signal. For example, and in accordance with FIGS. 1 and 2-1, the filtered signal may be forwarded at a second node (e.g., the amplifier port 228) to the amplifier 130 for amplification prior to the filtered signal being radiated from the antenna 124 as part of the wireless link 106.

Although the process 600 of FIG. 6 is described in the context of the transmission-line filter 128, including the transmission-line resonator 132, the process 600 of FIG. 6 is not to be limited by the context of the computing device 102 transmitting wirelessly or to the wireless-transceiver chipset 122. Instead, the process of FIG. 6 may include, for example, accepting a signal from a device or component other than the mixer 126, may include forwarding the signal to a device or component other than the amplifier 130, may pertain to receiving a signal wirelessly, and so forth. The process may also apply to both wired and wireless communications, including those operating at frequencies outside the 3 GHz to 300 GHz electromagnetic frequency spectrum.

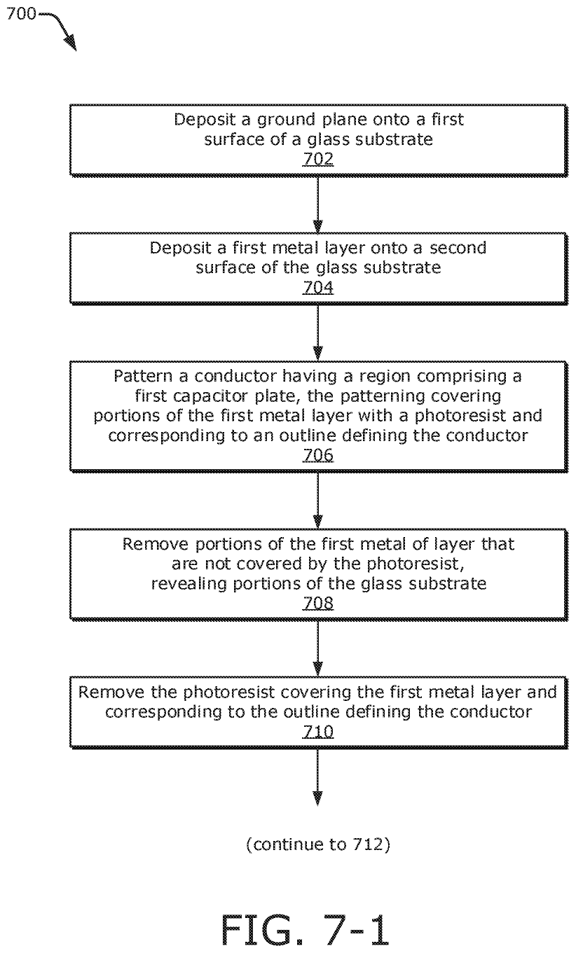

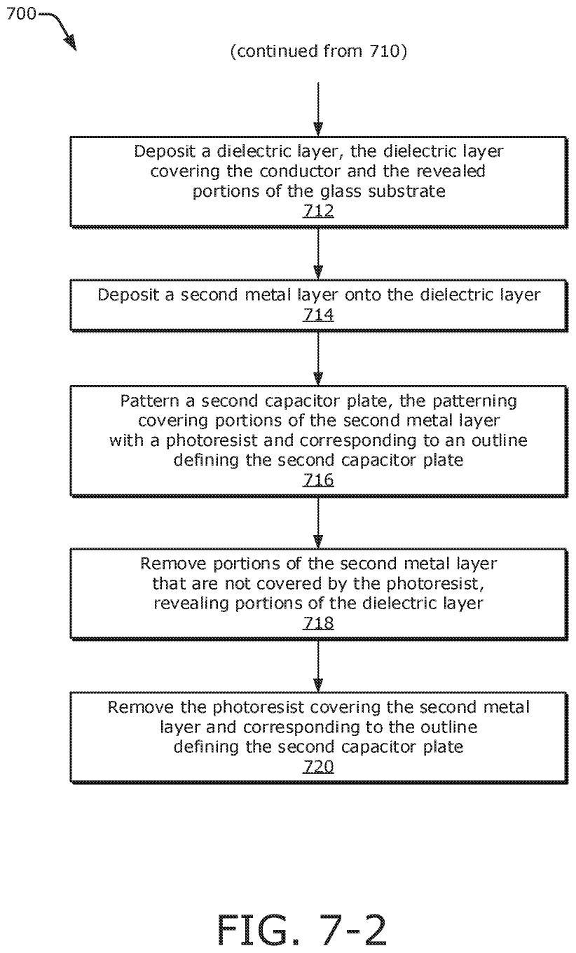

FIGS. 7-1 and 7-2 illustrate an example process 700 performed by semiconductor manufacturing tools to fabricate a transmission-line resonator as part of an integrated passive device. The process 700 is described in the form of a set of blocks 702-720 that specify operations that can be performed. However, operations are not necessarily limited to the order shown in FIG. 7 or described herein, for the operations may be implemented in alternative orders or in fully or partially overlapping manners. Thus, operations represented by the process 700 may be performed by semiconductor manufacturing tools including metal deposition tools, photolithography tools, or etching tools to fabricate the transmission-line resonator 132 of FIG. 1 and in accordance with details illustrated in FIGS. 3-1 and 3-2.

As illustrated by FIG. 7-1 and at 702, a deposition tool deposits the ground plane 212 onto the first side 306 of the glass substrate 304. The deposition tool may be a chemical vapor deposition (CVD) tool, a physical vapor deposition (PVD) tool, a sputtering tool, a plating tool, or the like. The ground plane may be comprised of a copper (Cu) material, an aluminum (Al) material, a titanium (Ti) material, a tungsten (W) material, or the like.

At 704, a deposition tool deposits a first metal layer (M1) onto the second side 308 of the glass substrate 304. The deposition tool may be a chemical vapor deposition (CVD) tool, a physical vapor deposition (PVD) tool, a sputtering tool, or a plating tool. The first metal layer (M1) may be comprised of a copper (Cu) material, an aluminum (Al) material, a titanium (Ti) material, a tungsten (W) material, or the like.

At 706, multiple tools perform a photolithography process to pattern the conductor 210 having a region comprising the first capacitor plate 206. The photolithography process includes masking, exposing, and developing a deposited layer photoresist such that portions of the first layer of metal (M1), corresponding to an outline defining the conductor 210, remain covered by portions of un-developed photoresist.

At 708, a dry-etch tool or a wet-etch tool removes portions of the first layer of metal (M1) that do not remain covered by photoresist, revealing portions of the glass substrate 304. At 710, an ashing tool removes the photoresist that covered the conductor 210 during the etching process at 708 and reveals the conductor 210.

As illustrated by FIG. 7-2 and continuing at 712, a deposition tool deposits the dielectric layer of material 312 to cover the conductor 210 and the revealed portions of the glass substrate 304. The deposition tool may be, for example, a chemical vapor deposition (CVD) tool, a physical vapor deposition (PVD) tool, a sputtering tool, or a plating tool. The dielectric layer of material 312 may, for example, be comprised of a polyimide (PI) material, a silicon nitride (SiNiₓ) material, a silicon oxynitride (SiOₓN_{y}) material, a borophosphosilicate glass (BPSG) material, an aluminum oxide (AlOₓ) material, a silicon dioxide (SiO₂) material, or the like.

At 714, a deposition tool deposits a second metal layer (M2) onto the dielectric layer of material 312. The deposition tool may be, for example, a chemical vapor deposition (CVD) tool, a physical vapor deposition (PVD) tool, a sputtering tool, or a plating tool. The second metal layer (M2) may be comprised of a copper (Cu) material, an aluminum (Al) material, a titanium (Ti) material, a tungsten (W) material, or the like.

At 716, multiple tools perform a photolithography process to pattern the second capacitor plate 208. The photolithography process includes masking, exposing, and developing a deposited layer photoresist such that portions of the second layer of metal (M2), corresponding to a pattern defining the second capacitor plate 208, remain covered by portions of un-developed photoresist.

At 718, a dry-etch or wet-etch tool removes portions of the second layer of metal (M2) that do not remain covered by photoresist, revealing portions of the dielectric layer of material 312. At 720, an ashing tool removes the photoresist that covered the capacitor 204 during the etching process at 718 and reveals the second capacitor plate 208.

Additional steps, using similar deposition, photolithography, and etching processes, may be introduced within the process 700 to complete fabrication of a transmission-line filter such as the transmission-line filter 128. As an example, additional steps may include simultaneously fabricating features of multiple transmission-line resonators. As another example, steps fabricating a plurality of via connections through the dielectric layer of material 312 (to connect M1 to M2), and through the glass substrate 304 (to connect a ground plane to different metal layers) may be included based on layout, and potential interferences from, other features that may be included as part of the transmission-line filter 128.

After fabricating the transmission-line filter 128 including the transmission-line resonator 132, a manufacturer may, for example, encapsulate the transmission-line filter 128 as a discrete component alone or with other such filers. The manufacturer may then integrate a wireless-transceiver chipset, such as the wireless-transceiver chipset 122 of FIG. 1, by mounting the transmission-line filter onto a printed circuit board (PCB) using surface mount (SMT) processes. In such an instance, the mixer 126 and the amplifier 130 of FIG. 1 may be discrete encapsulated components that, like the transmission-line filter 128, are also mounted using an SMT process, and wherein electrical traces formed as part of the PCB electrically couple together (e.g., in series) the mixer 126, the transmission-line filter 128 including the transmission-line resonator 132, and the amplifier 130.

As another example of integrating the wireless-transceiver chipset 122, the transmission-line filter 128 (including the transmission-line resonator 132) may be packaged by a manufacturer as part of a System-in-Package (SIP) or a Multi-Chip Package (MCP). In this instance, the mixer 126 and the amplifier 130 may be part of an integrated-circuit (IC) die in which they are either stacked vertically with the transmission-line filter 128 or arranged with the transmission-line filter 128 in a side-by-side fashion. To support integrating the transmission-line filter 128 as part of an SIP or MCP, metal layers of the transmission-line filter 128 (e.g., the first metal layer, the second metal layer, or another metal layer) may further include features such as one or more pads to accommodate wirebonding or flipchip bumping.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Further, items represented in the accompanying figures and terms discussed herein may be indicative of one or more items or terms, and thus reference may be made interchangeably to single or plural forms of the items and terms in this written description. Finally, although subject matter has been described in language specific to structural features or methodological operations, it is to be understood that the subject matter defined in the appended claims is not necessarily limited to the specific features or operations described above, including not necessarily being limited to the organizations in which features are arranged or the orders in which operations are performed.

1. An apparatus comprising:
a glass substrate having a first side and a second side that is opposite the first side;
a ground plane disposed on the first side of the glass substrate;
a transmission line including a conductor and a portion of the ground plane, the conductor formed from a first metal layer disposed on the second side of the glass substrate;
a first capacitor plate formed from the first metal layer;
a second capacitor plate formed from a second metal layer; and
a portion of a dielectric layer disposed between the first capacitor plate and the second capacitor plate.

2. The apparatus of claim 1, wherein the conductor and the first capacitor plate are contiguous within the first metal layer.

3. The apparatus of claim 2, wherein the conductor includes a region that comprises the first capacitor plate.

4. The apparatus of claim 1, wherein the ground plane disposed at the first side of the glass substrate is electrically connected to the first metal layer with at least one vertical interconnect access (via) connection that is routed through the glass substrate.

5. The apparatus of claim 1, further comprising:
a transmission-line filter including a first transmission line resonator and a second transmission line resonator, wherein:
the first transmission line resonator comprises the transmission line including the conductor, the first capacitor plate, and the second capacitor plate;
the second transmission line resonator comprises:
another transmission line including another conductor and another portion of the ground plane, the other conductor formed from the first metal layer disposed on the second side of the glass substrate;
a third capacitor plate formed from the first metal layer; and
a fourth capacitor plate formed from the second metal layer; and
another portion of the dielectric layer is disposed between the third capacitor plate and the fourth capacitor plate.

6. The apparatus of claim 1, wherein the first capacitor plate, the second capacitor plate, and the portion of the dielectric layer form a capacitor of an array of series-connected, cross-coupled capacitors.

7. The apparatus of claim 6, wherein:
the array of series-connected, cross-coupled capacitors includes:
a first group of capacitors connected together in a first series of capacitors, the first group of capacitors including the capacitor formed from the first capacitor plate and the second capacitor plate; and
a second group of capacitors connected together in a second series of capacitors; and
the first series of capacitors is coupled in parallel with the second series of capacitors.

8. The apparatus of claim 1, wherein the second side of the glass substrate has a surface roughness that is less than approximately one (1) nanometer (nm) and is configured to provide a smooth interface between the second side of the glass substrate and the conductor formed from the first metal layer.

9. The apparatus of claim 1, wherein the ground plane disposed on the first side of the glass substrate is electrically connected to the second metal layer with at least one vertical interconnect access (via) connection that is routed through the dielectric layer and the glass substrate.

10. The apparatus of claim 1, wherein the ground plane is formed from another metal layer.

11. The apparatus of claim 1, wherein the second capacitor plate is positioned substantially in a vertical alignment with the first capacitor plate to form a capacitor in conjunction with the portion of the dielectric layer disposed between the first capacitor plate and the second capacitor plate.

12. The apparatus of claim 1, further comprising:
a transmission-line resonator, the transmission-line resonator including the transmission line, the first capacitor plate, and the second capacitor plate;
a mixer coupled to the transmission-line resonator; and
an amplifier coupled to the transmission-line resonator.

13. The apparatus of claim 12, further comprising an antenna coupled to the amplifier.

14. The apparatus of claim 1, wherein:
the apparatus comprises at least part of a wireless-transceiver chipset that includes a transmission-line filter having a transmission-line resonator; and
the transmission-line resonator includes the conductor, the portion of the ground plane, the first capacitor plate, and the second capacitor plate.

15. The apparatus of claim 1, further comprising:
a transmission-line resonator; the transmission-line resonator including the transmission line, the first capacitor plate, and the second capacitor plate; the transmission-line resonator configured to resonate at an operating frequency,
wherein a length of the conductor of the transmission line is dimensioned based on a wavelength of the operating frequency.

16. The apparatus of claim 15, wherein the length of the conductor is less than approximately one-half (0.5) of the wavelength of the operating frequency of the transmission-line resonator.

17. A system comprising:
a glass substrate;
a ground plane disposed on a side of the glass substrate;
a first metal layer disposed on another side of the glass substrate;
a second metal layer disposed on the other side of the glass substrate beyond the first metal layer;
a dielectric layer disposed between the first metal layer and the second metal layer; and
a transmission-line resonator including:
propagation means for propagating a signal along at least a portion of the glass substrate;
a first capacitor plate formed from the first metal layer; and
a second capacitor plate formed from the second metal layer, a portion of the dielectric layer disposed between the first capacitor plate and the second capacitor plate.

18. The system of claim 17, further comprising:
linearity means for increasing a linear response of the signal propagated along the portion of the glass substrate, the linearity means including the first capacitor plate, the second capacitor plate, and the portion of the dielectric layer disposed therebetween.

19. A method for filtering a signal, the method comprising:
accepting the signal at a node;
propagating the signal along a conductor and a ground plane that are separated by a glass substrate;
routing the signal to a capacitor including a first plate and a second plate that are separated by a portion of a dielectric layer where the second plate is disposed on a same side of the glass substrate as the conductor;
responsive to the propagating and the routing, adjusting a characteristic of the signal; and
forwarding the signal at another node.

20. The method of claim 19, wherein the adjusting of the characteristic of the signal comprises rejecting some frequencies of the electromagnetic spectrum that are contained in the signal.

21. The method of claim 19, wherein the adjusting of the characteristic of the signal comprises passing a subset of frequencies of the electromagnetic spectrum that are contained in the signal.

22. The method of claim 19, wherein the routing of the signal to the capacitor comprises routing the signal to an array of series-connected, cross-coupled capacitors.

23. An apparatus comprising:
a glass substrate;
a first metal layer disposed on the glass substrate, the first metal layer including a conductor and a first set of capacitor plates;
a ground plane disposed on an opposite side of the glass substrate from the first metal layer, the conductor and a portion of the ground plane configured to operate as a transmission line;
a second metal layer including a second set of capacitor plates; and
a portion of a dielectric layer disposed between the first set of capacitor plates and the second set of capacitor plates.

24. The apparatus of claim 23, wherein:
the apparatus comprises at least part of a wireless-transceiver chipset that includes a transmission-line filter having a transmission-line resonator; and
the transmission-line resonator includes the conductor, the portion of the ground plane, the first set of capacitor plates, and the second set of capacitor plates.

25. The apparatus of claim 24, wherein the wireless-transceiver chipset is packaged as a multi-chip package (MCP) or a system-in-package (SIP).

26. The apparatus of claim 25, wherein one or more pads to accommodate wirebonding or flipchip bumping are formed from the first metal layer or the second metal layer.

27. The apparatus of claim 23, wherein the first set of capacitor plates, the second set of capacitor plates, and the portion of the dielectric layer form an array of series-connected, cross-coupled capacitors.

28. The apparatus of claim 27, wherein the array of series-connected, cross-coupled capacitors comprises a first group of capacitors that is coupled in parallel with a second group of capacitors.

29. The apparatus of claim 28, wherein the first group of capacitors is connected together in a first series of capacitors and the second group of capacitors is connected together in a second series of capacitors.

30. The apparatus of claim 29, wherein adjacent connections between consecutive capacitors in different groups of capacitors are disposed in different metal layers.
